(19) United States
(12) Patent Application Publication
(10) Pub. No.: US 2025/0087267 A1
(43) Pub. Date: Mar. 13, 2025

(54) MEMORY CELL ARRAY UNIT

(71) Applicant: SONY SEMICONDUCTOR SOLUTIONS CORPORATION, KANAGAWA (JP)

(72) Inventors: NOBUKAZU MURATA, KANAGAWA (JP); YOTARO MORI, KANAGAWA (JP); HARUHIKO TERADA, KANAGAWA (JP); YOSHIYUKI SHIBAHARA, KANAGAWA (JP)

(21) Appl. No.: 18/561,428

(22) PCT Filed: Mar. 3, 2022
(86) PCT No.: PCT/JP2022/009238

§ 371 Date: Nov. 16, 2023

(30) Foreign Application Priority Data
Jun. 8, 2021 (JP) 2021-095744

(51) Int. Cl. G11C 13/00

(52) U.S. Cl. CPC G11C 13/0069; G11C 13/004; G11C 13/0026; G11C 13/0028; G11C 2213/71

(57) ABSTRACT

A memory cell array unit according to an embodiment of the present disclosure includes a plurality of memory units arranged in a matrix. Each of the memory units includes a global bit line, a global word line, a memory cell array, a first connection unit, and a second connection unit. The first connection unit selects a word line to be coupled to the global word line. The second connection unit selects a bit line to be coupled to the global bit line, on the basis of address information obtained from the plurality of adjacent memory units.

### TECHNICAL FIELD

The present disclosure relates to a memory cell array unit.

### BACKGROUND ART

A memory cell array unit including a plurality of rewritable memory cells having a nonvolatile property has been known. The memory cell array unit is provided with a plurality of memory cell arrays, and each memory cell array is of a cross-point type in which memory cells are provided for respective intersections of a plurality of word lines and a plurality of bit lines (for example, reference is made to Patent Literature 1).

### CITATION LIST

### Patent Literature

Patent Literature 1: Japanese Unexamined Patent Application Publication No. 2010-020863

### SUMMARY OF THE INVENTION

In the above-described memory cell array unit, voltages are applied to all the memory cell arrays that are to be accessed at the same time under the same bias condition. This is because the same global bit line is to be coupled to all the memory cell arrays that are to be accessed at the same time. In this case, a charge/discharge current and a leakage current are increased when the bias condition is switched or a selection address is switched. Moreover, in the plurality of memory cell arrays that are to be accessed at the same time, it is not possible to selectively perform, at the same time, a set operation and a reset operation in which the bias conditions are different from each other. Accordingly, it is necessary to perform the set operation and the reset operation in order, which increases a latency. Therefore, it is desirable to provide a memory cell array unit that makes it possible to suppress a charge/discharge current and a leakage current and shorten a latency.

A memory cell array unit according to one embodiment of the present disclosure includes a plurality of memory units arranged in a matrix, and a control unit that controls reading and writing of data with respect to the plurality of memory units. Each memory unit includes a global bit line and a global word line, a memory cell array, a first connection unit, a second connection unit, and a storage unit. The memory cell array includes a plurality of word lines, a plurality of bit lines, and a plurality of memory cells provided one by one at intersections of the word lines and the bit lines. The first connection unit selects the word line to be coupled to the global word line. The second connection unit selects the bit line to be coupled to the global bit line. The storage unit stores address information obtained from the control unit. The second connection unit selects the bit line, on the basis of the address information obtained from the plurality of adjacent memory units.

In the memory cell array unit according to one embodiment of the present disclosure, in each of the memory units, the bit line to be coupled to the global bit line is selected on the basis of the address information obtained from the plurality of adjacent memory units. As a result, it is possible to limit the global bit line to be coupled to a power supply, thus making it possible to, for example, reduce a charge/discharge current at the time of selection switching and a leakage current of the power supply. In addition, because it is possible to select a different bias condition between the memory unit to be set and the memory unit to be reset, it is possible to, for example, perform a set operation and a reset operation at the same time.

### BRIEF DESCRIPTION OF THE DRAWINGS

FIG. 1 is a diagram illustrating an example of a schematic configuration of an information processing system according to an embodiment.

FIG. 2 is a diagram illustrating an example of a schematic configuration of a memory cell array unit of FIG. 1.

FIG. 3 is a diagram illustrating an example of a schematic configuration of each die of FIG. 2.

FIG. 4 is a diagram illustrating an example of a schematic configuration of each bank in FIG. 3.

FIG. 5 is a diagram illustrating an example of a schematic configuration of a memory cell array provided in each bank.

FIG. 6 is a diagram illustrating an example of a circuit configuration in each tile.

FIG. 7 is a diagram illustrating an example of a schematic configuration of each tile.

[FIG. 8] (A) of FIG. 8 is a diagram illustrating an example of a word line socket in each tile, and (B) of FIG. 8 is a diagram illustrating an example of a bit line socket in each tile.

FIG. 9 is a diagram illustrating an example of an erase operation using a bit line decoder of a lower right tile when focusing on four tiles.

FIG. 10 is a diagram illustrating an example of an erase operation using the bit line decoder of the lower right tile when focusing on four tiles.

FIG. 11 is a diagram illustrating an example of an erase operation using the bit line decoder of the lower right tile when focusing on four tiles.

FIG. 12 is a diagram illustrating an example of an erase operation using the bit line decoder of the lower right tile when focusing on four tiles.

FIG. 13 is a diagram illustrating an example of a word line decoder used together with the bit line decoder of the lower right tile when focusing on four tiles.

FIG. 14 is a diagram illustrating an example of a connection relationship between decoders in each tile.

FIG. 15 is a diagram illustrating an example of a write (set and reset) operation when focusing on four tiles.

FIG. 16 is a diagram illustrating an example of a write (set and reset) operation when focusing on four tiles.

FIG. 17 is a diagram illustrating a modification example of the connection relationship between the decoders in each tile.

FIG. 18 is a diagram illustrating a conventional example and an embodiment of a write (set and reset) operation.

### MODES FOR CARRYING OUT THE INVENTION

Hereinafter, an embodiment for practicing the present disclosure is described in detail with reference to the drawings. However, the embodiments described below are merely examples, and are not intended to exclude the application of various modifications and technologies not explicitly described below. Various modifications (e.g., combinations of embodiments) can be made to the present technology without departing from the scope thereof. In the following description of the drawings, the same or similar parts are denoted by the same or similar reference numerals. The drawings are schematic and do not necessarily correspond to actual dimensions, ratios, or the like. The drawings may include portions having different dimensional relationships and ratios.

### [Configuration]

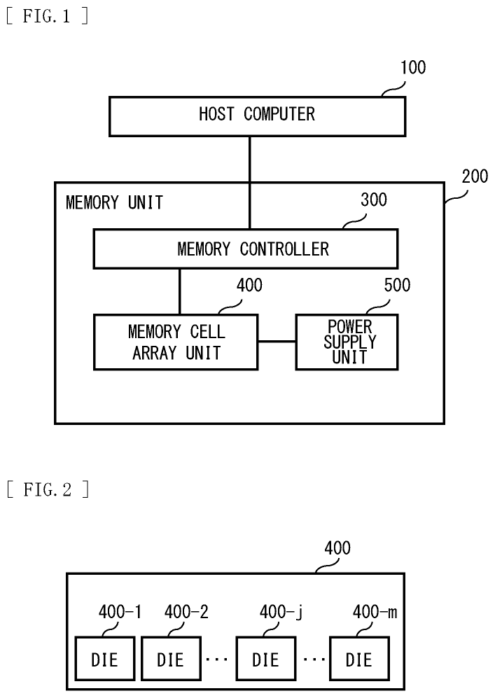

FIG. 1 illustrates an example of a functional block of an information processing system according to an embodiment. The information processing system includes a host computer 100 and a memory unit 200. The memory unit 200 includes a memory controller 300, one or more memory cell array units 400, and a power supply unit 500. FIG. 1 illustrates a state in which one memory cell array unit 400 is provided. The memory cell array unit 400 corresponds to a specific example of a “memory cell array unit” of the present disclosure.

### (Host Computer 100)

The host computer 100 controls the memory unit 200. Specifically, the host computer 100 issues a command that specifies a logical address of an access destination, and supplies the command and data to the memory unit 200. The host computer 100 receives the data outputted from the memory unit 200. Here, the command is for controlling the memory unit 200, and includes, for example, a write command that instructs a data write process or a read command that instructs a data read process. The logical address is an address allocated for each region for each access unit when the host computer 100 accesses the memory unit 200 in the address space defined by the host computer 100.

### (Memory Controller 300)

The memory controller 300 controls one or more memory cell array units 400. The memory controller 300 receives, from the host computer 100, the write command specifying the logical address. In addition, the memory controller 300 executes the data write process in accordance with the write command. In this write process, the logical address is converted to a physical address, and the data is written to the physical address. Here, the physical address is an address allocated in one or more memory cell array units 400 for each access unit when the memory controller 300 accesses one or more memory cell array units 400. Upon receiving the read command specifying the logical address, the memory controller 300 converts the logical address into the physical address and reads the data from the physical address. Then, the memory controller 300 outputs the read data to the host computer 100 as read data.

### (Power Supply Unit 500)

The power supply unit 500 supplies a desired voltage to one or more memory cell array units 400. For example, the power supply unit 500 supplies, to a later-described WL decoder 413, a voltage or the like used at the time of writing (at the time of setting, at the time of resetting) or at the time of reading (at the time of sensing). For example, the power supply unit 500 supplies, to a later-described BL decoder 414, a voltage or the like used at the time of writing (at the time of setting, at the time of resetting) or at the time of reading (at the time of sensing).

### (Memory Cell Array Unit 400)

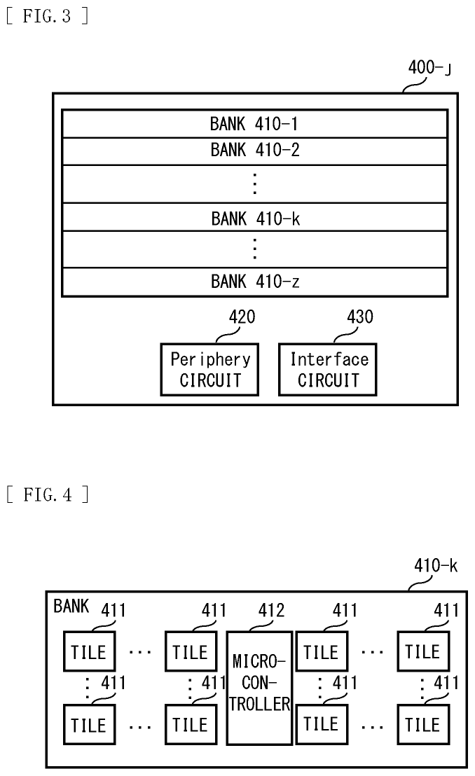

Next, the memory cell array unit 400 will be described. FIG. 2 illustrates an example of a functional block of the memory cell array unit 400. The memory cell array unit 400 is configured by, for example, a semiconductor chip. For example, as illustrated in FIG. 2, the memory cell array unit 400 has m-number of dies 400-j (1≤j≤m). Each die 400-j includes, for example, z-number of banks 410-k (1≤k≤z), a Periphery circuit 420 that performs an access control on each bank 410-k, and an Interface circuit 430 that performs a communication with the memory controller 300, as illustrated in FIG. 3.

For example, as illustrated in FIG. 4, each bank 410-k includes n-number of tiles 411 each having a 1-bit access unit, and a microcontroller 412 that controls the n-number of tiles 411. Under the control of the microcontroller 412, the respective banks 410-k operate the n-number of tiles 411 in a coordinated manner so as to access an n-bit data block as a whole.

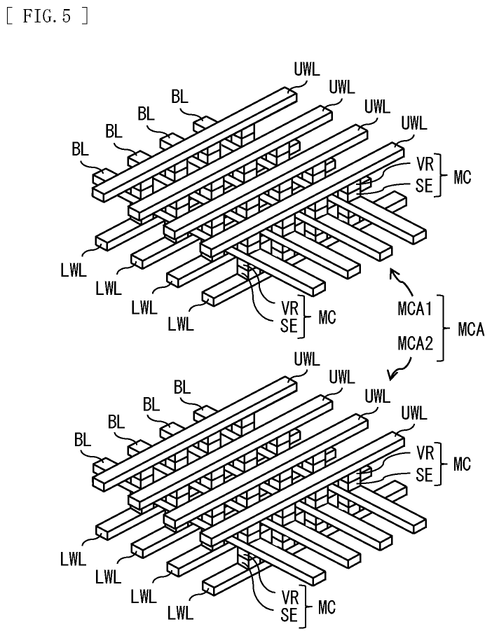

As illustrated in FIG. 5, the tiles 411 each have, for example, a memory cell array MCA including two layers of memory cell arrays MCA1 and MCA2. Each of the memory cell arrays MCA1 and MCA2 has, for example, a 1-bit memory cell MC at each intersection of an upper word line UWL and the bit line BL and at each intersection of a lower word line LWL and the bit line BL, as illustrated in FIG. 5. The memory cell MC is a writable non-volatile memory. The memory cell MC has a series structure of a resistance change element VR (Variable Resistor) that records 1-bit information on the basis of high or low resistance values, and a selection element SE (Selector Element) that has a bi-directional diode property. Hereinafter, the word line WL is appropriately used as a generic term for the upper word line UWL and the lower word line LWL.

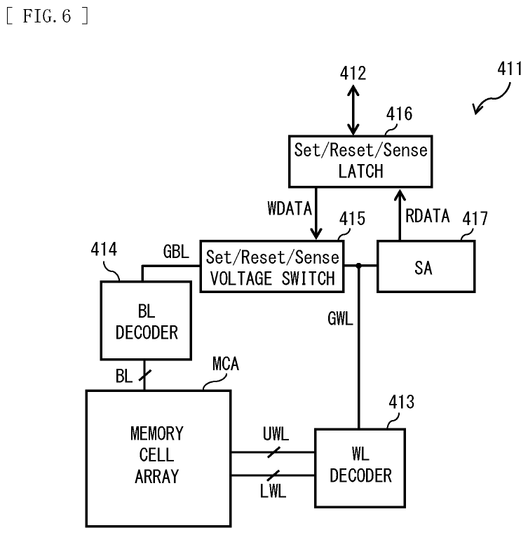

As illustrated in FIG. 6, each tile 411 includes, for example, a WL decoder 413, a BL decoder 414, a voltage switch 415, a latch 416, and a sense amplifier (SA) 417.

The WL decoder 413 applies a predetermined voltage to each word line WL on the basis of word line address information provided from the microcontroller 412. The BL decoder 414 selects one bit line BL from among the plurality of bit lines BL on the basis of bit line address information provided from the microcontroller 412.

The voltage switch 415 switches the voltages of the global word line GWL and the global bit line GBL on the basis of a control signal from the microcontroller 412 and the data of the set latch and reset latch of the latch 416. As a result, the voltages to be applied to the word line WL selected by the WL decoder 413 and to the bit line BL selected by BL decoder 414 are switched.

The latch 416 includes, for example, a write latch that latches write data WDATA and a sense latch that latches read data RDATA. The write data WDATA corresponds to one-bit data of the write data inputted to the bank 410-k. The read data RDATA corresponds to one-bit data of the read data to be read from the bank 410-k. The latch 416 further includes, for example, a set latch that latches the set data generated by the logic operation by the microcontroller 412 and a reset latch that latches the reset data generated by the logic operation by the microcontroller 20.

The tile 411 determines a value of the set latch and a value of the reset latch on the basis of a value of the write latch and a value of the sense latch. For example, when the value of the write latch equals to the value of the sense latch, it is not necessary to perform the write operation in the tile 411, and therefore the tile 411 sets the value of the set latch and the value of the reset latch to 0. For example, when the value of the write latch equals to 1 and the value of the sense latch equals to 0, it is necessary to perform the set operation in the tile 411, and therefore, the tile 411 sets the value of the set latch to 1 and the value of the reset latch to 0. For example, when the value of the write latch equals to 0 and the value of the sense latch equals to 1, it is necessary to perform the reset operation in the tile 411, and therefore, the tile 411 sets the value of the set latch to 0 and the value of the reset latch to 1.

The tile 411 latches the write data WDATA inputted from an interface circuit 430 into the write latch. The tile 411 latches the read data RDATA inputted from the sense amplifier 417 into the sense latch, and outputs the value of the sense latch to the interface circuit 430 under the control of the microcontroller 412. The tile 411 latches the set data inputted from the interface circuit 430 into the set latch, and outputs the value of the set latch to the voltage switch 415 under the control of the microcontroller 412. The tile 411 latches the reset data inputted from the interface circuit 430 into the set latch, and outputs the value of the reset latch to the voltage switch 415 under the control of the microcontroller 412.

The sense amplifier 417 compares the voltage of the global word line GWL obtained from WL decoder 413 with a reference voltage on the basis of the control signal from the microcontroller 412, and determines whether the resistance change element VR is in a low resistance state (LRS) or a high resistance state (HRS). The sense amplifier 417 generates a logic 0 in a case where the resistance change element VR is in the low resistance state (LRS), and generates a logic 1 in a case where the resistance change element VR is in the high resistance state (HRS), thereby generating the read data RDATA. The sense amplifier 417 outputs the generated read data RDATA to the latch 416.

### [Operation]

Next, an operation of the information processing system according to the present embodiment will be described.

As compared with the data unit for the host computer 100 to make an access to the memory cell array unit 400, the data unit for each bank 410-k to perform the writing and the reading is very small, and is in n bits (for example, 256 bits). In order to respond to a request (in particular, the read request) of the host computer 100 with a minimum delay, the memory controller 300 performs a read/write control by distributing the access granularity of the host computer 100 to the plurality of banks 410-k.

### (Set)

For example, when the set latch is 1 and the reset latch is 0, the tile 411 applies a positive 4.5 V to the bit line BL and −3.7 V to the lower word line LWL. As a result, the resistance change element VR of the memory cell MC at the intersection of the lower word line LWL and the bit line BL changes from the high resistance state (HRS) to the low resistance state (LRS). In this way, the memory cell MC is set. For example, when the set latch is 0 and the reset latch is 0, the tile 411 applies 0 V to the bit line BL and applies 0 V to 0.8 V to the lower word line LWL. As a result, a change in state does not occur in the memory cell MC at the intersection of the lower word line LWL and the bit line BL.

### (Reset)

For example, when the set latch is 0 and the reset latch is 1, the tile 411 applies −4.5 V to the bit line BL and applies +3.7 V to the lower word line LWL. As a result, the resistance change element VR of the memory cell MC at the intersection of the lower word line LWL and the bit line BL changes from the low resistance state (LRS) to the high resistance state (HRS). In this way, the memory cell MC is reset.

### (Read (Sense) Operation)

Upon receiving the read command and the logical address, the memory controller 300 converts the logical address into the physical address (a bank address and an intra-bank address), and then transmits the read command and the physical address to the Interface circuit 430. Upon receiving the read command and the physical address from the memory controller 300, the Interface circuit 430 transmits a sense command together with the in-bank address to the microcontroller 412 of the bank 410-k that corresponds to the received bank address.

The microcontroller 412 converts the specified intra-bank address into a word line address and a bit line address in the tile 411, and sets the word line address and the bit line address for each tile 411. The microcontroller 412 applies various control signals to the tile 411. As a result, the tile 411 applies a reading voltage to each of the memory cells MC to be read, via the word lines WL and the bit lines BL. The microcontroller 412 reads the data from each of the memory cells MC to be read, and fetches the data into the sense latch.

After receiving the read command from the memory controller 300, the Interface circuit 430 instructs the microcontroller 412 of each of the banks 410-k to read data at a timing when a predetermined period has elapsed. The predetermined period corresponds to a period from the reception of the read command from the memory controller 300 to the fetching of the data into the sense latch.

Each bank 410-k reads 1-bit data from the sense latch of each tile 411 in accordance with the command from the Interface circuit 430, and transmits the obtained n-bit data to the Interface circuit 430. The Interface circuit 430 transmits, to the memory controller 300, n×k bits of read data configured by n bits of data obtained from each bank 410-k. In this way, the read operation is performed.

### (Write (Set and Reset) Operation)

Upon receiving the write command, the logical address, and the write data, the memory controller 300 converts the logical address into the physical address (the bank address and the intra-bank address), and then transmits the write command and the physical address to the Interface circuit 430 via a command address bus. At this time, the memory controller 300 transmits the write data to the Interface circuit 430 via a data bus.

Upon receiving the write command, the physical address, and the write data from the memory controller 300, the Interface circuit 430 transmits, via the command address bus, the write command and the in-bank address to each tile 411 of the bank 410-k that corresponds to the received bank address. At this time, the Interface circuit 430 transmits, via the data bus, the write data one-bit by one-bit to each tile 411 of the bank 410-k that corresponds to the received bank address. Each tile 411 causes the write latch to hold the received 1-bit data. Subsequently, each tile 411 performs a similar operation to the read (sense) operation, thereby reading 1-bit data from the memory cell MC to be written, and fetching the data into the sense latch.

The microcontroller 412 then performs the following logic operations on the basis of the values held in the write latch and the sense latch in each tile 411 to determine the values of the set latch and the reset latch.

1. When the value of the write latch equals to the value of the sense latch, the microcontroller 412 sets the values of the set latch and the reset latch to 0, because it is not necessary to perform the write operation on the tile 411.

2. When the value of the write latch equals to 1 and the value of the sense latch equals to 0, the microcontroller 412 sets the value of the set latch to 1 and sets the value of the reset latch to 0, because it is necessary to perform the set operation on the tile 411.

3. When the value of the write latch equals to 0 and the value of the sense latch equals to 1, the microcontroller 412 sets the value of the set latch to 0 and sets the value of the reset latch to 1, because it is necessary to perform the reset operation on the tile 411.

Subsequently, the microcontroller 412 applies various control signals to the memory cell array MCA. As a result, the tile 411 applies, via the word line WL and the bit line BL, a set voltage to the memory cells MC of each tile 411 to be set. The microcontroller 412 writes the data to each memory cell MC to be set. At this time, the microcontroller 412 applies, via the word line WL and the bit line BL, a reset voltage to the memory cells MC of each tile 411 to be reset while performing the set operation on each memory cell MC to be set. In this way, the write (set and reset) operation is performed.

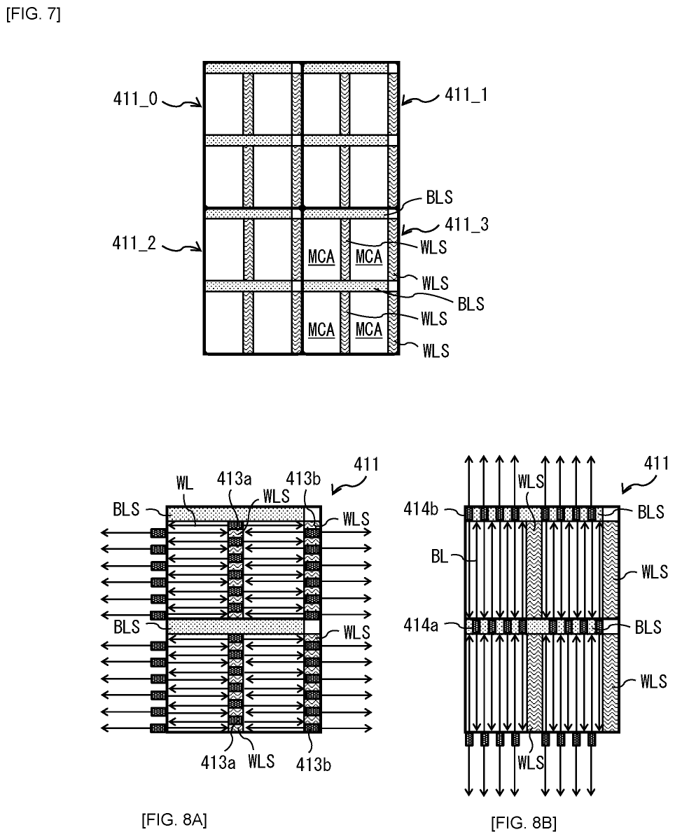

FIG. 7 illustrates an exemplary planar configuration of four tiles 411 in each bank 400-k. The tiles 411 each have, for example, four memory cell arrays MCA, four word line sockets WLS, and two bit line sockets BLS. In each tile 411, the four word line sockets WLS are assigned one by one for each memory cell array MCA. The respective word line sockets WLS are arranged adjacently to the allocated memory cell array MCA. In each tile 411, two bit line sockets BLS are allocated one by one for each of the two memory cell arrays MCA. The bit line sockets BLS are arranged adjacently to the two allocated memory cell arrays MCA.

(A) of FIG. 8 illustrates an exemplary planar layout of the word lines WL in the tiles 411 of FIG. 7. (B) of FIG. 8 illustrates an exemplary planar layout of the bit lines BL in the tiles 411 of FIG. 7. In each tile 411, two word line sockets WLS arranged in the middle are respectively provided with word line decoders 413. In (A) of FIG. 8, the word line decoder 413 is referred to as a word line decoder 413a. Further, in each tile 411, two word line sockets WLS arranged at end portions are respectively provided with the word line decoders 413. In (A) of FIG. 8, the word line decoder 413 is referred to as a word line decoder 413b. In each tile 411, the bit line sockets BLS arranged in the middle are provided with the bit line decoders 414. In (B) of FIG. 8, the bit line decoder 414 is referred to as a bit line decoder 414a. Further, in each tile 411, the bit line sockets BLS arranged at the end portions are provided with bit line decoders 414. In (B) of FIG. 8, the bit line decoder 414 is referred to as a bit line decoder 414b.

The two word line decoders 413a select one of the plurality of word lines WL arranged in the tile 411 to which the word line decoders 413a belong, and couple the selected one word line WL to the global word line GWL. The two word line decoders 413b select one of the plurality of word lines WL arranged in the tile 411 to which the word line decoders 413b belong and arranged over the tile 411 that is adjacent to the tile 411 to which the word line decoder 413b belongs, and couple the selected one word line WL to the global word line GWL.

The respective word lines WL that may be coupled to the global word line GWL by the word line decoders 413a are arranged in odd rows in the memory cell array MCA, for example. On the other hand, the respective word lines WL that may be coupled to the global word line GWL by the word line decoders 413b are arranged in even-numbered rows in the memory cell array MCA, for example. Thus, in the tile 411, when the word line address of the odd row is set, the word line WL is selected by the word line decoder 413a. When the word line address of the even-numbered row is set in the tile 411, the word line WL is selected by the word line decoder 413b.

The bit line decoder 414a selects one of the plurality of bit lines BL arranged in the tile 411 to which the bit line decoder 414a belongs, and couples the selected one bit line BL to the global bit line GBL. The bit line decoder 414b selects one of the plurality of bit lines BL arranged in the tile 411 to which the bit line decoder 414b belongs and arranged over the tile 411 that is adjacent to the tile 411 to which the bit line decoder 414b belongs, and couples the selected one bit line BL to the global bit line GBL.

The respective bit lines BL that may be coupled to the global bit line GBL by the bit line decoders 414a are arranged in even-numbered columns in the memory cell array MCA, for example. On the other hand, the respective bit lines BL that may be coupled to the global bit line GBL by the bit line decoders 414b are arranged in odd-numbered columns in the memory cell array MCA, for example. Thus, in the tile 411, when the bit line address of the odd-numbered column is set, the bit line BL is selected by the bit line decoder 414a. When the bit line address of the even-numbered column is set in the tile 411, the bit line BL is selected by the bit line decoder 414b.

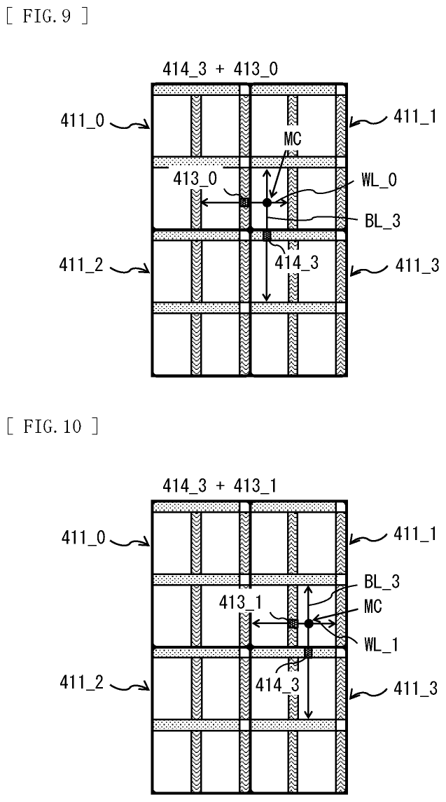

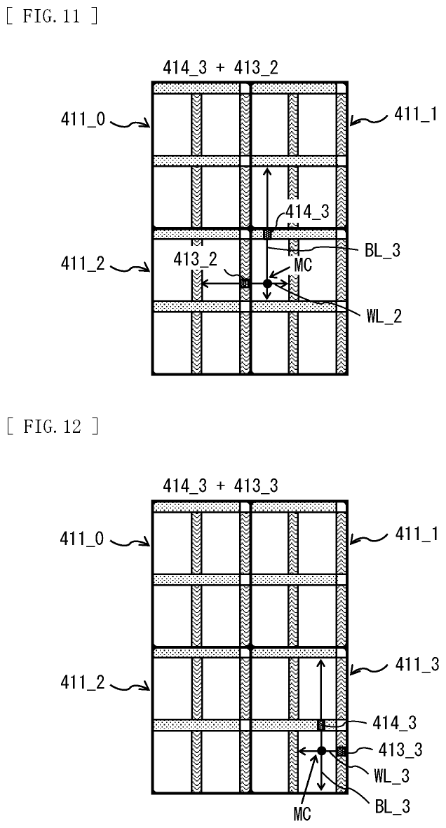

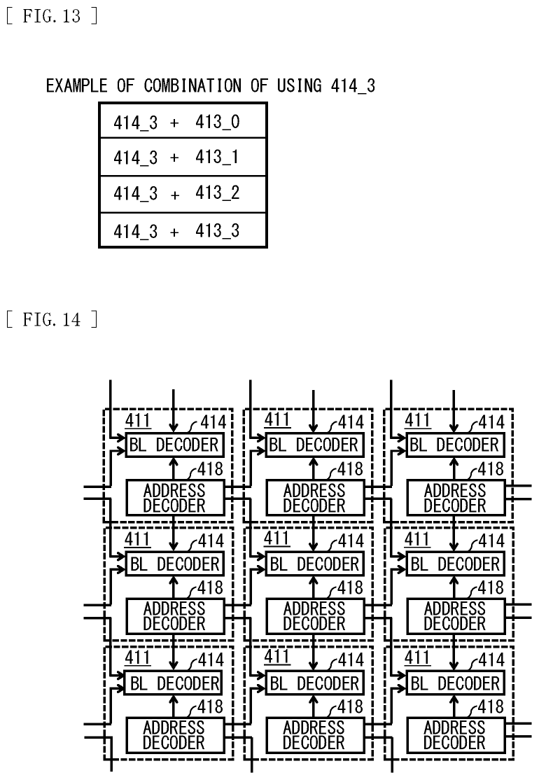

FIG. 9, FIG. 10, FIG. 11, and FIG. 12 illustrate an exemplary method of selecting the memory cells MC in the four tiles 411 in each bank 400-k. FIG. 13 illustrates a combination of decoders used in FIGS. 9 to 12. In FIGS. 9 to 12, the upper left tile 411 is referred to as 411_0, the upper right tile 411 is referred to as 411_1, the lower left tile 411 is referred to as 411_2, and the lower right tile 411 is referred to as 411_3. FIG. 9 to FIG. 13 illustrate combinations of decoders in which the bit line decoders 414 (414_3) belonging to the lower right tile 411_3 are used.

It is assumed that a word line address of an even-numbered row belonging to the subsequent stage (lower half) and a bit line address of an odd-numbered column are set from the microcontroller 412 to the upper right tile 411_0. At this time, in the tile 411_0, it not possible to select the memory cell MC designated by the microcontroller 412 using the word line decoder 413 (413_0) and the bit line decoder 414 (414_0) of the tile 411_0. Thus, for example, as illustrated in FIG. 9, the memory cell MC of the tile 411_1 is selected as the memory cell MC of the tile 411_0 by using the word line decoder 413b (413_0) of the tile 411_0 and the bit line decoder 414b (414_3) of the tile 411_1 adjacent to the lower right of the tile 411_0. At this time, the tile 411 to which the memory cell MC designated by the microcontroller 412 belongs is different from the tile 411 in which the selected memory cell MC is physically located. However, for the microcontroller 412, it is assumed that the tile 411 to which the memory cell MC designated by the microcontroller 412 belongs and the tile 411 to which the actually selected memory cell MC belongs constantly coincide with each other.

It is assumed that the word line address of the odd-numbered row belonging to the subsequent stage (lower half) and the bit line address of the odd-numbered column are set from the microcontroller 412 to the upper right tile 411_1. At this time, in the tile 411_1, it is not possible to select the memory cell MC designated by the microcontroller 412 using the word line decoder 413 (413_1) and the bit line decoder 414 (414_1) of the tile 411_1. Thus, for example, as illustrated in FIG. 10, the memory cell MC of the tile 411_1 is selected as the memory cell MC of the tile 411_1 by using the word line decoder 413a (413_1) of the tile 411_1 and the bit line decoder 414b (414_3) of the tile 411_3. At this time, the tile 411 to which the memory cell MC designated by the microcontroller 412 belongs is different from the tile 411 to which the bit line decoder 414 used for selection belongs. However, for the microcontroller 412, it is assumed that the tile 411 to which the memory cell MC designated by the microcontroller 412 belongs and the tile 411 to which the actually selected memory cell MC belongs constantly coincide with each other.

It is assumed that the word line address of the even-numbered row in the upper stage (upper half) and the bit line address of the odd-numbered column in the left stage (left half) are set from the microcontroller 412 to the tile 411_2 in the lower left. At this time, in the tile 411_2, it is not possible to select the memory cell MC designated by the microcontroller 412 using the word line decoder 413 (413_2) and the bit line decoder 414 (414_2) of the tile 411_2. Thus, for example, as illustrated in FIG. 11, the memory cell MC of the tile 411_3 is selected as the memory cell MC of the tile 411_2 by using the word line decoder 413b (413_2) of the tile 411_2 and the bit line decoder 414b (414_3) of the tile 411_3 adjacent to the right of the tile 411_2. At this time, the tile 411 to which the memory cell MC designated by the microcontroller 412 belongs is different from the tile 411 in which the selected memory cell MC is physically located. However, for the microcontroller 412, it is assumed that the tile 411 to which the memory cell MC designated by the microcontroller 412 belongs and the tile 411 to which the actually selected memory cell MC belongs constantly coincide with each other.

It is assumed that a word line address of an even-numbered row and a bit line address of an even-numbered column are set from the microcontroller 412 to the lower right tile 411_3. At this time, in the tile 411_3, it is possible to select the memory cell MC in the tile 411_3 using the word line decoder 413 (413_3) and the bit line decoder 414 (414_3) of the tile 411_3. Thus, for example, as illustrated in FIG. 12, the memory cell MC of the selected tile 411_3 is selected using the bit line decoder 414a (414_3) of the tile 411_3 and the word line decoder 413b (413_3) of the tile 411_3. At this time, the tile 411 to which the memory cell MC designated by the microcontroller 412 belongs and the tile 411 in which the selected memory cell MC is physically located coincide with each other.

FIG. 14 illustrates a configuration example of the decoder of each tile 411 and a connection example of each tile 411. Each tile 411 has an address decoder 418 that obtains the address information (word line address information and bit line address information) from the microcontroller 412.

In each tile 411, the address decoder 418 selects the word line WL on the basis of the set and reset selection information read from the latch 416, and couples the selected word line WL to the global word line GWL. The set and reset selection information is, for example, a set latch value and a reset latch value. In each tile 411, the address decoder 418 further determines (sets) a biasing condition of the selected word line WL on the basis of the set and reset selection information read from the latch 416 and the read data read from the latch 416. The read data is, for example, a value of a sense latch.

In the tile 411 (411_3), the BL decoder 414 acquires the address information from the address decoder 418 of the tile 411 (411_3) and the address decoders 418 of the left-adjacent, upper-left-adjacent, and upper-adjacent tiles 411 (411_0, 411_1, and 411_2). In tile 411 (411_3), the BL decoder 414 selects the bit line BL on the basis of the four obtained address information. The BL decoder 414 couples the selected bit line BL to the global bit line GBL. In the tile 411 (411_3), the BL decoder 414 further acquires the biasing condition of the selected word line WL from the address decoder 418 of the tile 411 (411_3) and the address decoders 418 of the left-adjacent, upper-left-adjacent, and upper-adjacent tiles 411 (411_0, 411_1, and 411_2). In the tile 411 (411_3), the BL decoder 414 determines (sets) the bias condition of the selected bit line BL on the basis of the obtained four conditions (the bias condition of the word line WL). In this manner, it is possible for the BL decoder 414 and the address decoder 418 to determine (set) the biasing conditions of the word line WL and BL decoder 414 for each tile 411.

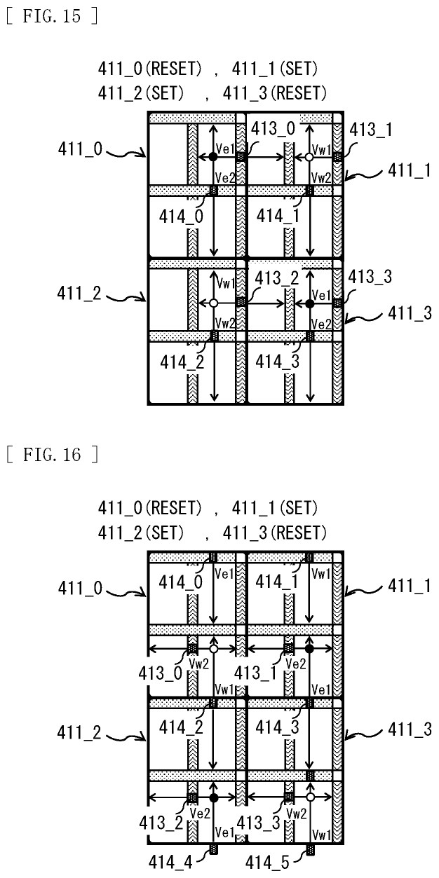

FIG. 15 and FIG. 16 illustrate an exemplary write (set and reset) operation in the four tiles 411 in each bank 400-k. FIG. 15 and FIG. 16 illustrate a state in which the set operation and the reset operation are performed at the same time in the four tiles 411. Specifically, FIG. 15 and FIG. 16 illustrate two tiles 411 (411_1 and 411_2) that perform the set operation and two tiles 411 (411_0 and 411_3) that perform the reset operation. FIG. 15 and FIG. 16 exemplify a voltage Vw1 as the bias condition of the word line WL when performing the set operation, and exemplify a voltage Vw2 as the bias condition of the bit line BL when performing the set operation. Further, FIG. 15 and FIG. 16 illustrate a voltage Ve1 as the bias condition of the word line WL when performing the reset operation, and illustrate a voltage Ve2 as the bias condition of the bit line BL when performing the reset operation.

For example, as illustrated in FIG. 15, in each tile 411, the word line decoder 413 and the bit line decoder 414 belonging to the own tile perform the set operation or the reset operation on the memory cells MC belonging to the own tile. At this time, the tile 411 to which the memory cell MC designated by the memory controller 300 belongs and the tile 411 to which the actually selected memory cell MC belongs coincide with each other.

Further, for example, as illustrated in FIG. 16, in each tile 411, the word line decoder 413 and the bit line decoder 414 belonging to the adjacent tiles perform the set operation or the reset operation on the memory cells MC belonging to the adjacent tiles. At this time, the tile 411 to which the memory cell MC designated by the memory controller 300 belongs differs from the tile 411 to which the actually selected memory cell MC belongs. Further, for example, as illustrated in FIG. 16, in each tile 411, the bit line decoders 414 belonging to adjacent tiles may be used to perform the set operation or the reset operation on the memory cell MC belonging to the own tile.

Incidentally, in FIGS. 15 and 16, the address of the bit line BL selected in the tile 411_1 that performs the set operation and the address of the bit line BL selected in the tile 411_3 that performs the reset operation are equal to each other. Further, in FIG. 15 and FIG. 16, the address of the bit line BL selected in the tile 411_0 that performs the reset operation and the address of the bit line BL selected in the tile 411_2 that performs the set operation are equal to each other.

Further, in FIGS. 15 and 16, the address of the word line WL selected in the tile 411_1 that performs the set operation and the address of the word line WL selected in the tile 411_0 that performs the reset operation are equal to each other. Further, in FIGS. 15 and 16, the address of the word line WL selected in the tile 411_3 that performs the reset operation and the address of the word line WL selected in the tile 411_2 that performs the setting operation are equal to each other.

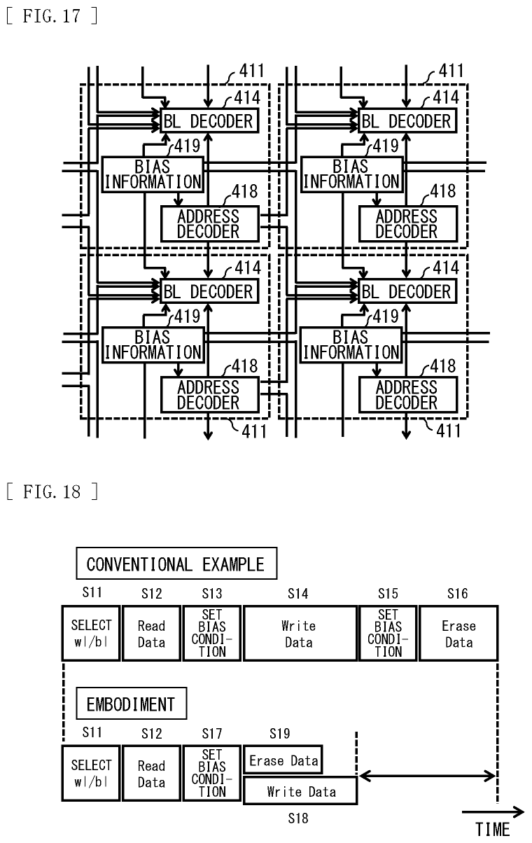

FIG. 17 illustrates a modification example of an internal configuration of each tile 411 illustrated in FIG. 14. In addition to the BL decoder 414 and the address decoder 418, each tile 411 may further include a register 419 in which bias information is stored. In this case, the register 419 stores the bias condition (the bias condition of the word line WL and the bias condition of the bit line BL) in its own tile 411 as the bias information.

In each tile 411, the address decoder 418 selects the word line WL on the basis of the set and reset selection information read from the latch 416. In each tile 411, the address decoder 418 further determines (sets) the biasing condition of the selected word line WL on the basis of the set and reset selection information read from the latch 416 and the read data read from the latch 416. In each tile 411, the address decoder 418 stores the determined (set) biasing condition of the word line WL in the register 419.

In the tile 411 (411_3), the BL decoder 414 acquires the address information from the address decoder 418 of the tile 411 (411_3) and the address decoders 418 of the left-adjacent, upper-left-adjacent, and upper-adjacent tiles 411 (411_0, 411_1, and 411_2). In the tile 411 (411_3), the BL decoder 414 selects the bit line BL on the basis of the four address information acquired.

The BL decoder 414 couples the selected bit line BL to the global bit line GBL. In the tile 411 (411_3), the BL decoder 414 further obtains the biasing condition of the selected word line WL from the register 419 of the tile 411 (411_3) and the registers 419 of the left-adjacent, upper-left-adjacent, and upper-adjacent tiles 411 (411_0, 411_1, and 411_2). In the tile 411 (411_3), the BL decoder 414 determines (sets) the bias condition of the selected bit line BL on the basis of the obtained four conditions (the bias condition of the word line WL). The BL decoder 414 stores the determined (set) biasing condition of the bit line BL in the register 419. In this manner, it is possible for the BL decoder 414 and the address decoder 418 to determine (set) the biasing conditions of the word line WL and the BL decoder 414 for each tile 411.

FIG. 18 illustrates a conventional example and an embodiment of a write (set and reset) operation. First, upon receiving the write command, the logical address, and the write data, the memory controller 300 converts the logical address into the physical address, and then transmits the write command and the physical address (the bank address and the intra-bank address) to the Interface circuit 430 via the command address bus. At this time, the memory controller 300 transmits the write data to the Interface circuit 430 via the data bus.

Upon receiving the write command, the physical address, and the write data from the memory controller 300, the Interface circuit 430 transmits, via the command address bus, the write command and the in-bank address to the microcontroller 412 of the bank 410-k that corresponds to the received bank address. At this time, the Interface circuit 430 transmits, via the data bus, the write data one bit by one bit to each tile 411 of the bank 410-k that corresponds to the received bank address. Each tile 411 causes the write latch to hold the received 1-bit data.

Subsequently, each tile 411 performs the read (sense) operation to the read 1-bit data from the memory cell MC to be written and fetch the read data into the sense latch. Each tile 411 converts, for example, the designated intra-bank address into the word line address and the bit line address, and sets the word line address and the bit line address.

In each tile 411, the address decoder 418 selects the word line WL on the basis of the address information obtained from the microcontroller 412 and the set and reset selection information read from the latch 416 (step S11). In the tile 411 (411_3), the BL decoder 414 acquires the address information from the address decoder 418 of the tile 411 (411_3) and the address decoders 418 of the left-adjacent, upper-left-adjacent, and upper-adjacent tiles 411 (411_0, 411_1, and 411_2). In the tile 411 (411_3), the BL decoder 414 selects the bit line BL on the basis of the obtained four pieces of address information (step S11).

The microcontroller 412 applies various control signals to each tile 411. As a result, each tile 411 applies the reading voltage to each memory cell MC to be written via the word line WL and the bit line BL. The microcontroller 412 reads the data from each memory cell MC to be written, and fetches the data into the sense latch (step S12).

Next, in the tile 411 (411_3), the BL decoder 414 obtains the biasing condition of the selected word line WL from the address decoder 418 of the tile 411 (411_3) and the address decoders 418 of the left-adjacent, upper-left-adjacent, and upper-adjacent tiles 411 (411_0, 411_1, and 411_2). In the tile 411 (411_3), the BL decoder 414 determines (sets) the bias condition of the selected bit line BL on the basis of the obtained four conditions (the bias condition of the word line WL). As described above, the BL decoder 414 and the address decoder 418 determine (set) the biasing condition of the word line WL and BL decoder 414 for each tile 411 (step S17).

The microcontroller 412 applies various control signals to each tile 411. As a result, each tile 411 applies a predetermined voltage to the memory cells MC to be written (set and reset) via the word lines WL and the bit lines BL (steps S18 and S19). In this way, the set operation and the reset operation are performed at the same time.

### [Effects]

Next, effects of the information processing system according to the present embodiment will be described.

Conventionally, the same biasing conditions are set for all memory cell arrays that are to be accessed at the same time (S13 and S15). This is because the same global bit line is to be coupled to all memory cell arrays that are to be accessed at the same time. Moreover, in a plurality of memory cell arrays that are to be accessed at the same time, it is not possible to selectively perform a set operation and a reset operation in which bias conditions are different from each other. Therefore, it is necessary to perform the set operation and the reset operation in order (S14 and S16). Therefore, a latency becomes longer.

In contrast, in the present embodiment, in each tile 411, the bit line BL to be coupled to the global bit line GBL is selected on the basis of the address information obtained from the plurality (three) of adjacent tiles 411. As a result, it is possible to limit the global bit line GBL to be coupled to the power supply 500, and thus to, for example, reduce a charge/discharge current at the time of selection switching and a leakage current of the power supply. In addition, because it is possible to select the different bias conditions between the tile 411 to be set and the tile 411 to be reset, for example, it is possible to perform the set operation and the reset operation at the same time.

Further, in the present embodiment, the set and reset selection information obtained from the microcontroller 412 is stored in the latch 416, and the word line WL is selected on the basis of the set and reset selection information obtained from the latch 416. As a result, it is possible to limit the global word line GWL to be coupled to the power supply 500, and thus to, for example, reduce the charge/discharge current at the time of selection switching and the leakage current of the power supply. In addition, because it is possible to select the different bias conditions between the tile 411 to be set and the tile 411 to be reset, for example, it is possible to perform the set operation and the reset operation at the same time.

Further, in the present embodiment, the bias condition of the selected word line WL is set on the basis of the set and reset selection information obtained from the latch 416 and the read data (sense latch value) obtained from the memory cell MC (the latch 416). As a result, it is possible to select the different bias conditions between the tile 411 to be set and the tile 411 to be reset, and thus to, for example, perform the set operation and the reset operation at the same time.

Further, in the present embodiment, the bias condition of the selected bit line BL is set on the basis of the bias condition of the selected word line WL obtained from the plurality of adjacent tiles 411. As a result, it is possible to select the different bias conditions between the tile 411 to be set and the tile 411 to be reset, and thus to, for example, perform the set operation and the reset operation at the same time.

Although the present technology has been described with reference to the embodiments, the present disclosure is not limited to the above-described embodiments, and various modifications are possible. It should be noted that the effects described in this specification are only exemplified. The effects of the present disclosure are not limited to the effects described herein. The present disclosure may have effects other than the effects described herein.

For example, the present disclosure may also be configured as follows.

(1)

A memory cell array unit including:
a plurality of memory units arranged in a matrix; and
a control unit that controls reading and writing of data with respect to the plurality of memory units,
the memory units each including
a global bit line and a global word line,
a memory cell array that includes a plurality of word lines, a plurality of bit lines, and a plurality of memory cells provided one by one at intersections of the word lines and the bit lines,
a first connection unit that selects the word line to be coupled to the global word line,
a second connection unit that selects the bit line to be coupled to the global bit line, and
a storage unit that stores address information obtained from the control unit, in which
the second connection unit selects the bit line, on the basis of the address information obtained from the plurality of adjacent memory units.
   (2)

The memory cell array unit according to (1), in which
the storage unit stores set and reset selection information obtained from the control unit, and
the first connection unit selects the word line, on the basis of the set and reset selection information obtained from the storage unit.
   (3)

The memory cell array unit according to (1) or (2), in which the first connection unit sets a bias condition of the selected word line, on the basis of the set and reset selection information obtained from the storage unit and read data obtained from the memory cell.

(4)

The memory cell array unit according to any one of (1) to (3), in which the second connection unit sets a bias condition of the selected bit line, on the basis of the bias condition of the selected word line obtained from the plurality of adjacent memory units.

(5)

The memory cell array unit according to any one of (1) to (4), in which, in each of the memory units:
the plurality of word lines includes a plurality of first word lines arranged in the corresponding memory unit and a plurality of second word lines arranged in the corresponding memory unit and over the memory unit that is adjacent to the
the plurality of bit lines includes a plurality of first bit lines arranged in the corresponding memory unit and a plurality of second bit lines arranged in the corresponding memory unit and over the memory unit that is adjacent to the corresponding memory unit;
the first connection unit includes a third connection unit that selects the first word line to be coupled to the global word line, and a fourth connection unit that selects the second word line to be coupled to the global word line; and
the second connection unit includes a fifth connection unit that selects the first bit line to be coupled to the global bit line, and a sixth connection unit that selects the second bit line to be coupled to the global bit line.

In the memory cell array unit according to one embodiment of the present disclosure, in each memory unit, a bit line to be coupled to a global bit line is selected on the basis of address information obtained from a plurality of adjacent memory units. As a result, it is possible to limit the global bit line to be coupled to a power supply, and thus to, for example, reduce a charge/discharge current at the time of selection switching and a leakage current of the power supply. In addition, because it is possible to select different bias conditions between the memory unit to be set and the memory unit to be reset, for example, it is possible to perform a set operation and a reset operation at the same time. Therefore, it is possible to suppress a charge/discharge current and the leakage current to a low level and to shorten a latency. It should be noted that the effects of the present disclosure are not necessarily limited to the effects described herein, and may be any of the effects described in this specification.

The present application claims the benefit of Japanese Priority Patent Application JP2021-095744 filed with the Japan Patent Office on Jun. 8, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A memory cell array unit comprising:
a plurality of memory units arranged in a matrix; and
a control unit that controls reading and writing of data with respect to the plurality of memory units,
the memory units each including
a global bit line and a global word line,
a memory cell array that includes a plurality of word lines, a plurality of bit lines, and a plurality of memory cells provided one by one at intersections of the word lines and the bit lines,
a first connection unit that selects the word line to be coupled to the global word line,
a second connection unit that selects the bit line to be coupled to the global bit line, and
a storage unit that stores address information obtained from the control unit, wherein
the second connection unit selects the bit line, on a basis of the address information obtained from the plurality of adjacent memory units.

2. The memory cell array unit according to claim 1, wherein
the storage unit stores set and reset selection information obtained from the control unit, and
the first connection unit selects the word line, on a basis of the set and reset selection information obtained from the storage unit.

3. The memory cell array unit according to claim 1, wherein the first connection unit sets a bias condition of the selected word line, on a basis of the set and reset selection information obtained from the storage unit and read data obtained from the memory cell.

4. The memory cell array unit according to claim 3, wherein the second connection unit sets a bias condition of the selected bit line, on a basis of the bias condition of the selected word line obtained from the plurality of adjacent memory units.

5. The memory cell array unit according to claim 1, wherein, in each of the memory units:
the plurality of word lines includes a plurality of first word lines arranged in the corresponding memory unit and a plurality of second word lines arranged in the corresponding memory unit and over the memory unit that is adjacent to the corresponding memory unit;
the plurality of bit lines includes a plurality of first bit lines arranged in the corresponding memory unit and a plurality of second bit lines arranged in the corresponding memory unit and over the memory unit that is adjacent to the corresponding memory unit;
the first connection unit includes a third connection unit that selects the first word line to be coupled to the global word line, and a fourth connection unit that selects the second word line to be coupled to the global word line; and
the second connection unit includes a fifth connection unit that selects the first bit line to be coupled to the global bit line, and a sixth connection unit that selects the second bit line to be coupled to the global bit line.

6. The memory cell array unit according to claim 5, wherein
the first connection unit sets a bias condition of the selected word line, on a basis of the set and reset selection information obtained from the storage unit and read data obtained from the memory cell, and
the second connection unit sets a bias condition of the selected bit line, on a basis of the bias condition of the selected word line obtained from the plurality of adjacent memory units.
